(19) United States
(12) Patent Application Publication
(10) Pub. No.: US 2014/0118954 A1
(43) Pub. Date: May 1, 2014

(54) ELECTRONIC DEVICE WITH HEAT-DISSIPATING STRUCTURE

(71) Applicants: Xiu Shi, Beijing (CN); Min Yin, Beijing (CN)

(72) Inventors: Xiu Shi, Beijing (CN); Min Yin, Beijing (CN)

(73) Assignee: Telefonaktiebolaget L M Ericsson (publ), Stockholm (SE)

(21) Appl. No.: 14/119,813

(22) PCT Filed: Jun. 28, 2011
(86) PCT No.: PCT/CN2011/076478

§ 371 Date: Nov. 22, 2013

(51) Int. Cl. H05K 7/20

(52) U.S. Cl. CPC H05K 7/2039
USPC 361/720

(57) ABSTRACT

There is disclosed an electronic device having a heat-dissipating structure. The electronic device comprises a circuit board; a heat conduction plate arranged to face the circuit board, and dissipate heat generated by the circuit board only in a direction parallel to the heat conduction plate. According to the present invention, the electronic device is particular suitable for the application wherein the electronic device will be stacked up on another electronic device and requires no any forced convection arrangement such as a fan.

### TECHNICAL FIELD

The present invention generally relates to the heat-dissipating technique, and more particularly, relates to an electronic device having a heat-dissipating structure.

### BACKGROUND

Usually, the electronic device comprises a lot of electronic components which will generate heat during operations. Therefore, it requires heat-dissipating measures to be taken in the electronic device to release the heat generated by these electronic components. The heat-dissipating measures can usually be divided into two types, i.e., natural convection and forced convection. In general, the natural convection is a more preferable option than the forced convection in the field of, for example, telecommunication, because of its merits of high reliability, low cost, no noise, and etc.

FIG. 1 schematically illustrates a conventional natural convection heat-dissipating structure of an electronic device, particularly a telecommunication device. As illustrated in FIG. 1, the telecommunication device includes an enclosure, at least one circuit board hosted therein. The circuit board has various components arranged thereon, which will generate an amount of heat during their operations. To dissipate the heat generated from those components, a natural convection heat-dissipating measure is used in the device. In such a device, the heat will firstly be transferred to the enclosure (particular top and bottom sides thereof) mainly through air convection, and then dissipated to the ambient via the enclosure. The enclosure may also have a plurality of vents, for example, at the two opposite sides as shown, to improve the heat transfer. However, for this structure, the heat is transferred mainly through air and thus there is a big thermal resistance in the heat transfer from those components to the enclosure. Hence, such a convectional heat-dissipating structure is only suitable to devices with low power consumption. In some applications in which the device will generate a huge amount of heat due to high power consumption, the convectional heat-dissipating structure can not provide sufficient heat-dissipation.

In European patent application publication EP1284592 entitled “Telecommunication device including a housing having improved heat conductivity”, there is disclosed another natural convection heat-dissipating structure as illustrated in FIG. 2. As shown in this figure, the structure includes a housing 10 having improved heat conductivity and heat radiation. The housing 10 comprises an inner wall 16, an outer wall 15 and a hollow space 17 formed therebetween and for receiving refrigerant 19. The housing 10 receives a plurality of units 23 each mounting thereon a plurality of integrated circuits or internal circuits 24. For the sake of efficient heat conduction, a heat conductive sheet 25 is disposed between each integrated circuit 24 and the inner surface of the inner wall 16 of the housing 10. The heat conducted from the circuit to the inner wall will be absorbed by the refrigerant 19, and the refrigerant 19 is circulated and the heat is conducted to the outer wall 15, and finally from the outer surface of outer wall 15 of the housing 10, heat is dissipated to the ambient. Therefore, in this illustrated structure, the thermal resistance from internal circuit 24 to the outer wall 15 of housing 10 is greatly reduced and thus the heat-dissipating of the device is improved.

From the above description of the prior art, it is clear that both of the two convection heat-dissipating structures will transfer the heat or at least most of the heat generated by the components to the top and bottom surfaces of the enclosure firstly and then dissipate heat from these surfaces to the ambient. That is to say, the top and bottom surfaces of the enclosure play a very important role in the heat-dissipating.

However, it may confront some problems in practical application. As an example, in some specific applications for the electronic device such as telecommunication device, among others, for the purpose of space saving, it will usually require several devices to be stacked on top of each other to mount in a cabinet. In such a case, the top surface of a device is usually covered by a bottom surface of another device and the bottom of the device usually covers a top surface of a further device, which results in significant reduction of the heat-dissipating efficiency of the top and bottom surfaces of the device. Accordingly, the heat dissipation of these devices will get worse greatly.

### SUMMARY OF THE INVENTION

In view of the foregoing problems in the existing natural convection heat-dissipating structures, there is needed an improved structure for the electronic device. Accordingly, an objection of the present invention is to provide an electronic device with heat-dissipating structure, which obviates or at least mitigates at lease part of the above problems.

In one aspect, there is provided an electronic device having a heat-dissipating structure, which comprises a circuit board and a heat conduction plate. The heat conduction plate can be arranged to face the circuit board and dissipate heat generated by the circuit board substantially only in a direction parallel to the heat conduction plate. Having such a heat conduction plate, the electronic device will be suitable to the application wherein several electronic devices are stacked on top of each other.

In embodiments of the invention, the heat generated from the potential hot spot will be transferred to the heat conduction plate firstly and then dissipated to external environment substantially only in a direction parallel to the heat conduction plate. Therefore, the electronic device as provided in the present invention is particularly suitable to an application wherein several devices are required to stack on top of each other. Particularly, in a preferable embodiment, the heat is transferred directly to the heat conduction plate through heat conduction, in addition to heat convection and the heat radiation, and thus the heat can be transferred more efficiently. In another preferable embodiment, the heat can be transferred to the ambient through the heat radiator and/ or vents provided on at least one of surfaces of the electronic device from which the heat is dissipated and therefore, the heat can be dissipated to the ambient efficiently. Therefore, the preferable embodiment can even be suitable for the electronic device with rather high power consumption.

Other features and advantages of the embodiments of the present invention will also be apparent from the following description of specific embodiments when read in conjunction with the accompanying drawings, which illustrate, by way of example, the principles of embodiments of the invention.

### BRIEF DESCRIPTION OF THE DRAWINGS

Embodiments of the invention are presented in the sense of examples and their advantages are explained in greater detail below, with reference to the accompanying drawings, wherein

FIG. 1 is a diagram showing a conventional natural convection heat-dissipating structure in prior art;

FIG. 2 is a diagram showing another natural convection heat-dissipating structure in prior art;

FIG. 3 schematically illustrates a section diagram of an electronic device according to an embodiment of the present invention;

FIG. 4 schematically illustrates an exploded perspective view of an electronic device according to an embodiment of the present invention;

FIG. 5 schematically illustrates a perspective diagram of a upper heat conduction arrangement according to an embodiment of the present invention;

FIG. 6 schematically illustrates an elevation diagram of one of the flanges according to an embodiment of the present invention;

FIG. 7 schematically illustrates a perspective diagram of a lower heat conduction arrangement according to an embodiment of the present invention; and

FIG. 8 schematically illustrates a perspective diagram of an electronic device according to an embodiment of the present invention.

### DETAILED DESCRIPTION OF EMBODIMENTS

Embodiments of the present invention provide an electronic device having a novel heat-dissipating structure which will be detailed hereinafter by exemplary embodiments.

It should be appreciated that, while this specification contains many specific implementation details, they should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

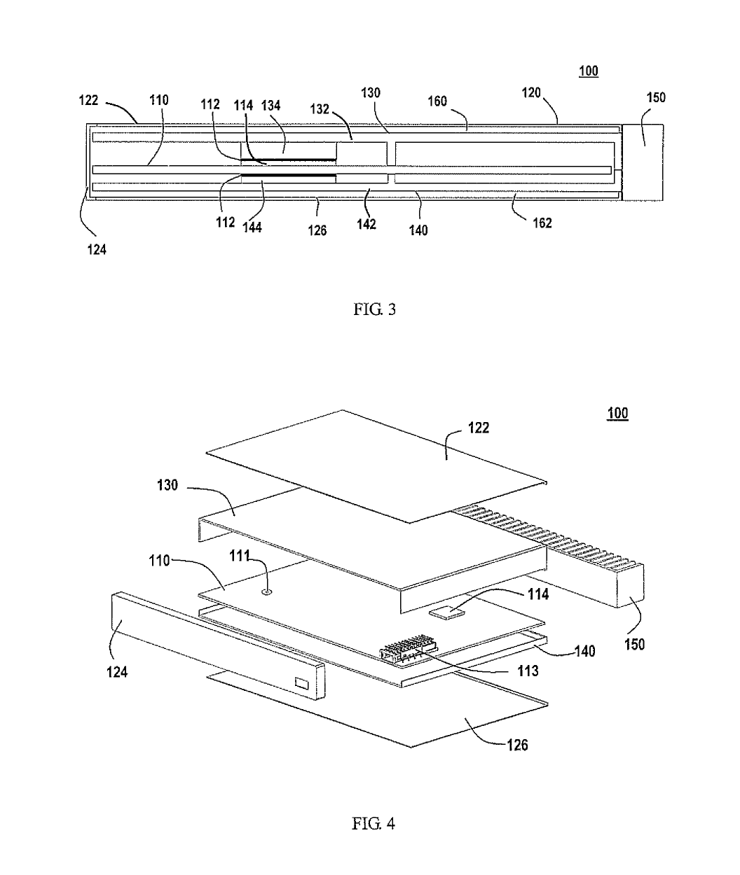

Hereinafter, reference will be made to FIGS. 3 to 8 to describe the exemplary embodiments of the present inventions in detail.

In FIG. 3 is illustrated a schematic section diagram of an electronic device 100 according to an embodiment of the present invention, which is taken parallel to a side of the electric device and perpendicular to a front panel of the device. As illustrated in FIG. 3, the electronic device 100 includes a circuit board 110, a housing 120, an upper heat-dissipating arrangement 130, a lower heat-dissipating arrangement 140 and an optional heat radiator 150.

The circuit board 110 such as printed circuit board is a key functional element of the electronic device and has one or more electronic components arranged thereon. For the sake of simplify, only one component 114 is shown. As has been described hereinbefore, the component will generate heat and thus the region on the circuit board 110 corresponding to the component can form a potential hot spot 112. However, it can be appreciated that the potential hot spot 112 can be any region on the circuit board 110 which will generate a large amount of heat and is not limited to a region corresponding to one or more components.

To dissipate heat generated from the component, the heat-dissipating arrangements 130, 140 comprise an upper heat conduction plate 132 and a lower heat conduction plate 142 respectively disposed on and below the circuit board 110, each of which is arranged to face the circuit board 110. Thus, the heat conduction plate 132, 142 can absorb heat from the circuit board 110 by both heat convection and heat radiation. Additionally, the heat conduction plate 132, 142 can comprise flanges extending therefrom in a direction substantially perpendicular to the surface of the heat conduction plate. One or more of these flanges are arranged to be in thermal contact with the ambient so as to dissipate heat absorbed by the heat conduction plate into ambient. The flanges will be detailed hereinafter with reference FIGS. 5 to 7.

To improve heat transfer efficiency, there are preferably arranged heat conduction elements 134, 144 respectively protruded from the upper and lower heat conduction plates 132, 142. The heat conduction elements 134, 144 are configured to be surface-contacted with the potential hot spot 112 on the two opposite sides of the circuit board 110, and thus heat from the hot spot will be conducted to the heat conduction plates directly. That is to say, besides the heat convection and radiation, the heat conduction plate can also receive heat from the circuit board 110 though heat conduction. Hence, it further speeds up the heat transferring from the circuit board. Additionally, it is also preferred if the surface of the heat conduction plate 132,142 can be treated to obtain a high heat emissivity, since the heat radiation will be further improved.

Furthermore, optionally and preferably, a heat radiator 150 is arranged, for example, at the back of the electronic device to facilitate the heat-dissipating to the ambient. However, the skilled in the art will appreciate that the heat radiator 150 can be arranged at any other surface of the electronic device from which heat are permitted to dissipate, such as right side, left side, or front side, and more than one heat radiators can be arranged to further facilitate the heat-dissipating.

The housing 120 for hosting the circuit board 110 comprises a top cover 122, a front panel 124, and a bottom cover 126. Part of flanges of the heat conduction plate can also server as side plates or black plate, or optionally the electronic device can also comprise one or more of side plates and a back plate. As shown in FIG. 3, the top cover 122 covers the upper heat conduction plate 132, the bottom cover 126 cover the lower heat conduction plate 142 and the front panel 124 engages with both the top and bottom covers 122 and 126. In such a way, the housing 120, together with a part of the heat-dissipating arrangement 130 and 140 (specifically, flanges of the heat conduction plates, serving a part of the housing), enclosures the circuit board 110 therein.

According to embodiments of the present invention, each of the upper and lower heat conduction plates 132 and 142 is configured to dissipate heat generated by the circuit board substantially only in a direction parallel to the heat conduction plate. In case of the illustrated device, heat is dissipated to the peripheral surfaces of the housing, instead of the top and bottom surfaces.

In an embodiment of the present invention, there are arranged a gap 160 between the heat conduction plate 132 and the surface of the housing which the heat conduction plate 132 faces, and a gap 162 between the heat conduction plate 142 and the surface of the housing which the heat conduction plate 142 faces. The gaps 160, 162 can be usually small, because a small gap will take a function of blocking heat exchange between the conductions plates and top and bottom inner surfaces of the housing 120. And preferably, the gap can be sized so that little and more preferably no air convection flow can be formed therein. In this way, the heat transfer between the heat conduction plates and the top and bottom inner surface of the housing will be little due to substantially no air convection and low heat conductivity of air.

To reduce heat radiation from the conduction plate 132, 142 to the undesirable surface of the housing, the surfaces of the heat conduction plate 132, 142 facing the housing can be treated so as to have low heat emissivity. With the treated surface, radiation heat transfer will be very limited because of the low heat emissivity of these surfaces. On the other hand, the surfaces of the housing facing the heat conduction plate 132, 142 can also be treated as surfaces with low heat emissivity to further reduce the heat radiation. It should be noted that it is also feasible to only treat some of these surfaces.

In an alternative embodiment of the present invention, these gaps 160, 162 between the conductions plates 132, 142 and top and bottom inner surfaces of the housing 120 can be filled with thermal isolation material to prevent heat exchange between the conductions plates and top and bottom inner surfaces of the housing 120. In such way, the heat transfer between the conductions plates 132, 142 and top and bottom inner surfaces of the housing 120 will be further reduced and therefore, very limited amount of heat can be transferred to the top and bottom surfaces of the housing 120. Of course, it is also feasible if no thermal isolation material is filled when the gap is sized properly.

Accordingly, almost all heat is transferred to the ambient through peripheral surfaces and substantially no amount of heat can be transferred to the top and bottom surface of the housing. Thus, the heat-dissipating structure will work efficiently and the influence to heat-dissipating is very limited even if several equipments are stacked on top of each other.

To facilitate understanding the structure of the electronic device as provided in the present invention thoroughly and fully, FIG. 4 schematically illustrates an exploded perspective view of an electronic device 100 according to an embodiment of the present invention. As is clear from FIG. 4, the electronic device 100 includes the circuit board 110, the two heat conduction plates 132 and 142, the top cover 122, the front panel 124, the bottom cover 126, and the heat radiator 150. The exemplary circuit board 110 has an electronic component 114 and a connector 113 to interface with the other device. Additionally, there are also some holes 111 (only one hole is shown in this figure) in the circuit board 110, which are used to fix the print circuit board and the heat conduction plates together. The front panel 124 also has an opening through which the connector 113 can be accessed.

FIG. 5 schematically illustrates the upper heat-dissipating arrangement 130 according to an embodiment of the present invention. As illustrated in FIG. 5, the upper heat-dissipating arrangement 130 comprises a heat conduction plate 132, which can be made of any material with high heat conductivity, such as aluminum, copper or alloy thereof. The heat conduction plate 132 is preferable provided with flanges 135, 136, 137. These flanges can also serve as part of side surface of the housing as stated hereinabove. Heat absorbed by the heat conduction plate 132 can be dissipated to the ambient via these flanges.

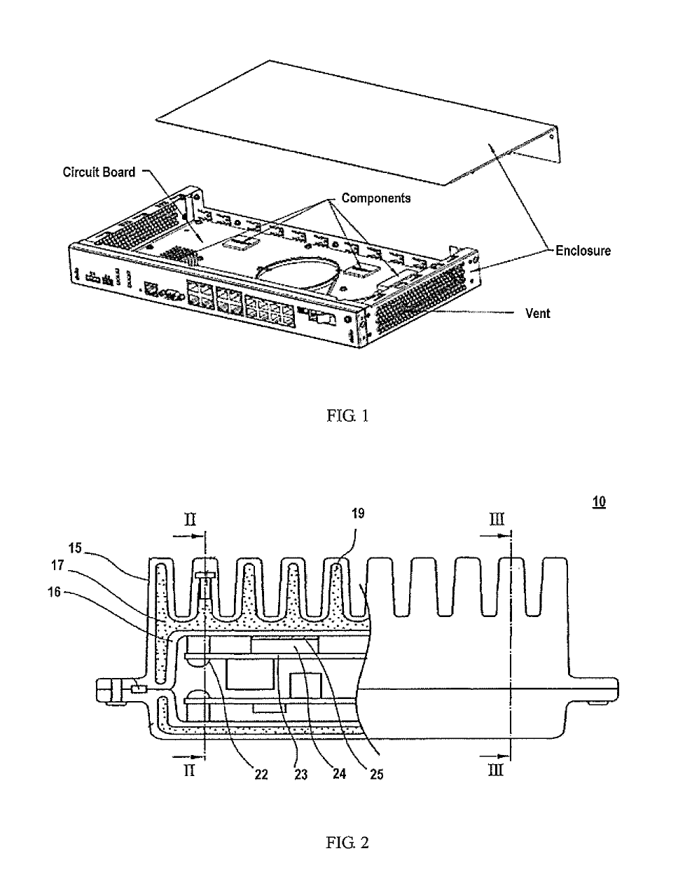

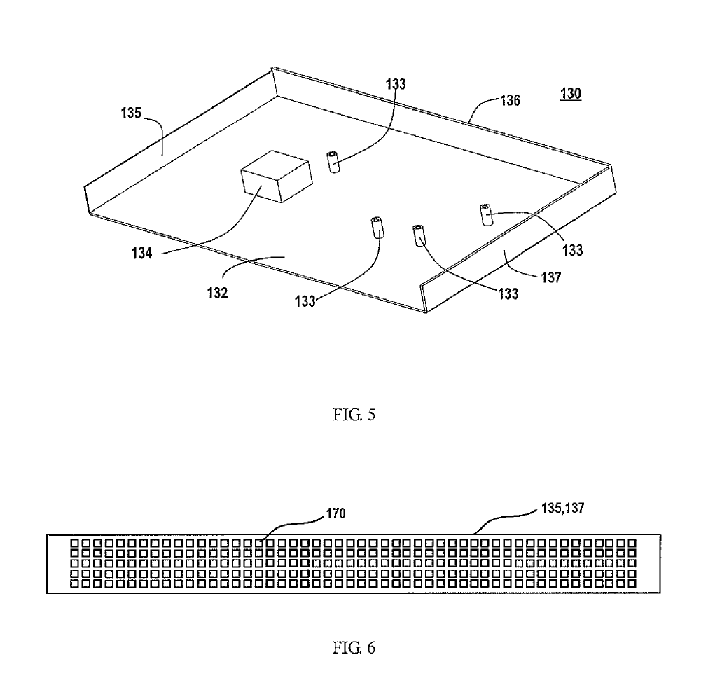

Preferably, one or more of flanges 135, 136 and 137 can have heat radiator attached therewith, and in the illustrated device in FIGS. 1 and 8, flange 136 serving as the back side of the housing 120 is attached with a heat radiator 150. Alternatively or additionally, in one or more of the flanges, there can also be provided a vent to facilitate the heat transferring. FIG. 6 schematically illustrates an elevation diagram of one of the flanges according to an embodiment of the present invention, for example flange 135 or 137, wherein the flange has a large amount of vents provided. With these vents, part of heat can be dissipated therethrough and thus the efficiency of the heat transfer will be improved.

Additionally, the heat conduction plate 132 preferably has one or more conduction elements 134 protruded therefrom. In FIG. 5, only one heat conduction element 134 is shown. However, the skilled in the art can appreciate that if the circuit board has more than one potential hot spot, the heat conduction plate 132 will be provided with more than one heat conduction elements accordingly. The heat conduction element 124 is shown as a heat conduction block. Actually, the heat conduction element 124 can be in any other shape suitable for contacting with the potential hot spot, for example in a cylinder shape, a hexagon shape and so on. As has described above, the heat conduction element 134 will be surface-contacted with the potential hot spot 112, and directly conduct the heat generated from the hot spot to the heat conduction plate 132. Preferable, at the end of the heat conduction block, there can be provided a heat conduction pad or sheet which is made of soft heat conduction material, such as a silicone thermal soft pad or sheet, so as to have a good contact with the hot spot.

Furthermore, as illustrate in FIG. 5, the heat conduction plate 132 can also have several hollow studs 133 provided thereon which are used to fix the heat conduction plate and the board circuit together.

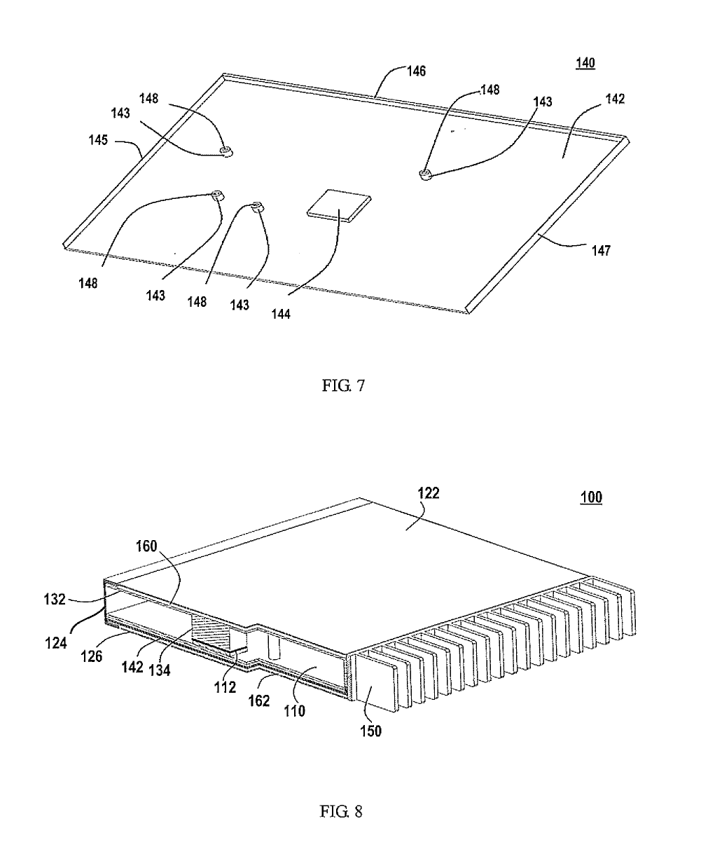

FIG. 7 schematically illustrates a perspective diagram of a lower heat conduction arrangement 140 according to an embodiment of the present invention. As shown in FIG. 7, the lower heat conduction arrangement 140 has a similar structure to the upper heat conduction arrangement 130, i.e., includes a heat conduction plate 142, three flanges 145, 146, 147, a heat conduction element 144 and several stubs 143 with hole 148 therein. However, locations of the components of the top and bottom heat conduction plates are opposite and they may have different sizes. The lower heat conduction plate 140 is suitable to be arranged below the circuit board and conduct heat from the back side of the circuit board 110. Due to the fact that the backside usually has few significantly protrusive electronic components, the height of the corresponding parts of the lower heat conduction arrangement 140 can be smaller than those of the upper heat conduction arrangement 130. However, the skilled in the art will appreciate that the height of the correspond parts of the bottom heat conduction plate 140 can be equal to or bigger than those of the top heat conduction plate 130 dependent on conditions of arrangement of the components of the circuit board.

FIG. 8 illustrates a perspective diagram of an electronic device according to an embodiment of the present invention, which has been assembled together and has been cut to show internal components. As illustrated FIG. 8, the top heat conduction plate 132, the circuit board 110, the bottom heat conduction plate 142 are assembled together by hollow stubs provided on the top and bottom heat conduction plates 132 and 142, holes provided in the circuit board 110 and several fasteners. The top cover 122 and the bottom cover 126 are fitted to the top and bottom heat conduction plates 132, 142 with gaps 160 and 162 provided therebetween respectively.

The front panel 124, which is formed for example by a plate and two flanges extended from two opposite sides, is fitted at the facade of the electronic device (the facade is illustrated towards to the top left in FIG. 8). As illustrated in FIG. 8, the two flanges are abutting to the top cover 122 and the bottom cover 126 respectively, so as to form, together with the top cover 122 and the bottom cover 126, a flat top surface and a flat bottom surface respectively.

A heat radiator or a heat sink 150 is mounted on backside of the electronic device, the heat radiator comprise a base and a plurality dissipating elements such as dissipating fins protruded therefrom and the base is attached onto the backside of the electronic device 100. It is noted that the heat radiator 150 is illustrated only for the purpose of illustration, and any other suitable heat radiators can also be used, such as a heat radiator comprising heat-dissipating posts in a quadrate shape, in a hexagonal shape and so on.

With such an arrangement, the heat generated from the hot spot 112 will be conducted to the top or bottom heat conduction plates 132, 142 through the heat conduction elements 134, 144 and the heat can also be transferred to the heat conduction plates via both heat radiation and heat convection, and in turn the heat is dissipated to the ambient through the heat radiator. If there are provided vents in one or more sides, the heat-dissipating can be further improved. Therefore, the present invention can achieve efficient heat-dissipating without fans and thus it is possible to adopt a natural convection heat-dissipating structure when several electronic devices are stacked up.

It could be appreciated that although two heat conduction arrangements 130, 140 are used to dissipate heat in the above embodiments, less or more heat conduction arrangement will be also feasible. Further, in the above embodiments, the heat radiator is described as being arranged at backside of the electronic device. However, it is also possible to arrange it on any position of the device (such as the front panel, both sides of the electronic device and so on) other than those from which the heat is undesirable to dissipate.

Additionally, it is also possible that the surface of the heat conduction plate with back towards to the circuit board can serve as a top or bottom cover of the enclosure. In such a case, the top and/or bottom cover 122 and 126 can be omitted.

In the embodiments for example as shown in FIGS. 4 and 6, the flanges of the heat conduction plate are extended towards only one side. However, the present invention is not limited thereto, and the flanges can also be extended in two opposite sides as required.

It is noted that the electronic device can be a telecommunication device such as a switch, router and so on. However, the present invention is not limited thereto, and any other electronic device to which the present invention is applicable is also possible.

In the detailed description of the present invention, it is set forth the application in which several electronic devices will be stacked on top of each other. However the present invention is not limited thereto. By modifying slightly the device, the electronic device can also be used in an application wherein several electronic devices will be arranged side by side.

In the embodiments described above, the upper and lower heat conduction plates and the circuit board are assembled by hollow stubs, holes and fastener. However, other means known to the skilled in the art is also possible.

Besides, it is desirable that the heat is dissipated only in the direction parallel to the heat conduction plate. However, in the practical application, it is difficult to reach such an ideal condition due to various factors. There might be a small quantity of heat transferred to the top or bottom side, but it is tiny and ignorable. Therefore, such a case can be considered a case wherein the heat generated by the circuit board (110) is dissipated substantially only in a direction parallel to the heat conduction plate (132; 142).

Finally, it should also be appreciated that the above description provides examples to describe the invention and to enable a person of ordinary skill in the art to make and use the invention. However, this above description is not intended to limit the invention to the precise terms set forth. Thus, while the invention has been described in detail with reference to the examples set forth above, those of ordinary skill in the art may made alterations, modifications and variations to the examples without departing from the scope of the invention.

1. An electronic device having a heat-dissipating structure, comprising:
a circuit board; and
a heat conduction plate arranged to face the circuit board, and dissipate heat generated by the circuit board substantially only in a direction parallel to the heat conduction plate.

2. The electronic device according to claim 1, further comprising:
at least one heat conduction element protruded from the heat conduction plate, wherein the heat conduction element is configured to be surface-contacted with a potential hot spot in the circuit board.

3. The electronic device according to claim 1, further comprising a cover for covering the heat conduction plate, and wherein a gap is provided between the heat conduction plate and the cover.

4. The electronic device according to claim 3, wherein the gap is sized so that substantially no air convection is formed in the gap.

5. The electronic device according to claim 3, wherein a thermal isolation material is filled in the gap.

6. The electronic device according to claim 1, wherein a surface of the heat conduction plate with back towards the circuit board is a surface-treated surface with reduced heat emissivity.

7. The electronic device according to claim 1, wherein a surface of the heat conduction plate facing the circuit board is a surface-treated surface with enhanced heat emissivity.

8. The electronic device according to claim 2, wherein the heat conduction element is a heat conduction block protruded from the heat conduction plate.

9. The electronic device according to claim 8, wherein the heat conduction element further comprises a heat conduction pad provided on an end of the heat conduction block, and the heat conduction pad is arranged to be surface-contacted with the potential hot spot in the circuit board directly.

10. The electronic device according to claim 1, further comprising a hollow mounting stud provided on the heat conduction plate, for fixing the heat conduction plate to the circuit board.

11. The electronic device according to claim 1, wherein the heat conduction plate has a flange in thermal contact with ambient.

12. The electronic device according to claim 1, wherein the electronic device comprises two said heat conduction plates with the circuit board sandwiched therebetween.

13. The electronic device according to claim 3, wherein an inner surface of the cover facing the heat conduction plate is a surface-treated surface with reduced heat emissivity.

14. The electronic device according to claim 1, wherein the electronic device comprises a heat radiator arranged on at least one of surfaces of the electronic device from which the heat is dissipated.

15. The electronic device according to claim 1, further comprising a vent arranged in at least one of surfaces of the electronic device from which the heat is dissipated.

16. The electronic device according to claim 1, wherein the electronic device is a switcher or a router.

17. The electronic device according to claim 1, wherein the heat conduction plate is made one of aluminum, copper, and alloy thereof.

18. The electronic device according to claim 1, wherein the electronic device comprises a heat sink arranged on at least one of surfaces of the electronic device from which the heat is dissipated.

19. The electronic device according to claim 2, wherein the heat conduction element is in one of a cylinder shape and a hexagon shape.

20. The electronic device according to claim 9, wherein the heat conduction pad is made of a silicone thermal soft pad.
